(19) United States
(12) Patent Application Publication
(10) Pub. No.: US 2023/0212083 A1
(43) Pub. Date: Jul. 6, 2023

(54) METHOD FOR MANUFACTURING CERAMIC SUSCEPTOR

(71) Applicant: MiCo Ceramics Ltd., Gyeonggi-do (KR)

(72) Inventors: Hyeon Jun LEE, Gyeonggi-do (KR); Chang Min YOO, Gyeonggi-do (KR)

(21) Appl. No.: 18/069,496

(22) Filed: Dec. 21, 2022

(30) Foreign Application Priority Data
Dec. 23, 2021 (KR) 10-2021-0185962

(51) Int. Cl. C04B 37/02; B28B 11/24; B28B 1/14; B28B 1/30; C04B 35/117; C04B 35/63; C04B 35/626

(52) U.S. Cl. CPC C04B 37/021; B28B 1/14; B28B 1/30; B28B 11/243; C04B 35/117; C04B 35/6261; C04B 35/6303; C04B 2235/36; C04B 2235/785; C04B 2235/786; C04B 2235/3206; C04B 2235/3217; C04B 2235/3225; C04B 2235/6025; C04B 2237/40; C04B 2237/343; C04B 2237/706; H01L 21/6833

(57) ABSTRACT

Disclosed is a method for manufacturing a ceramic susceptor, the method including: preparing ceramic sheets; preparing a lamination structure of a molded body, in which the ceramic sheets are laminated and a conductive metal layer for electrodes is disposed between the ceramic sheet laminated products; and sintering the lamination structure of the molded body, wherein the preparing of the ceramic sheets includes: obtaining a vitrified first additive powder by heat-treating a slurry containing MgO, SiO₂, and CaO; preparing a slurry by mixing an Al₂O₃ powder with the first additive powder, a second additive powder containing a MgO powder, and a third additive powder containing a Y₂O₃ powder; and forming the ceramic sheets by tape casting the slurry.

### CROSS-REFERENCE TO RELATED APPLICATION(S)

This application is based on and claims priority under 35 U.S.C. 119 to Korean Patent Application No. 10-2021-0185962, filed on Dec. 23, 2021, in the Korean Intellectual Property Office, the disclosure of which is herein incorporated by reference in its entirety.

### FIELD

The present disclosure relates to a ceramic susceptor and, particularly, to a method for manufacturing a ceramic susceptor having a uniform composition and relieved temperature dependency of material properties.

### BACKGROUND

Semiconductor devices or display devices are typically manufactured by sequentially depositing a plurality of thin film layers including dielectric layers and metal layers on glass substrates, flexible substrates, or semiconductor wafer substrates, followed by patterning. These thin film layers are sequentially deposited on substrates by chemical vapor deposition (CVD) or physical vapor deposition (PVD). Examples of CVD include low pressure CVD (LPCVD), plasma enhanced CVD (PECVD), metal organic CVD (MOCVD), and the like. In chamber apparatuses of CVD and PVD systems for performing such semiconductor processes, a ceramic susceptor is widely used as an electrostatic chuck for holding various substrates, such as a glass substrate, a flexible substrate, and a semiconductor wafer substrate, or as a heater for accurate temperature control and heat treatment requirements in plasma deposition processes and the like to attain precise processes, such as providing finer wirings in semiconductor devices.

Especially, for ceramic electrostatic chucks that are mainly used for a poly etch process in dry etching processes, conventional ceramic lamination type electrostatic chucks, such as multi-layer ceramics (MLC), may cause a problem that as the temperature rises from room temperature to around 100° C. to 150° C., the electrostatic force changes from Coulomb type (high resistance) to Johnsen-Rahbek type (medium resistance), and thus the electrostatic force is significantly increased and the discharge time of residual charges is longer, resulting in difficulty in de-chucking. As such, the ceramic electrostatic chucks have increased temperature dependency of material properties, resulting in structural defects, causing the deterioration in electric/mechanical properties.

### Related Patent Documents

Japanese Patent Publication NO. JP 2017-103389 (2017.06.08)
Japanese Patent No. JP 6088346 (2017.03.01)

### SUMMARY

Accordingly, the present disclosure has been made in view of the above-mentioned problems, and an aspect of the present disclosure is to provide a method for manufacturing a ceramic susceptor employing a ceramic sheet with a uniform composition having high volume resistivity without temperature dependence.

In accordance with an aspect of the present disclosure, there is provided a method for manufacturing a ceramic susceptor. The method includes: preparing ceramic sheets; preparing a lamination structure of a molded body, in which the ceramic sheets are laminated and a conductive metal layer for electrodes is disposed between the ceramic sheet laminated products; and sintering the lamination structure of the molded body, wherein the preparing of the ceramic sheets includes: obtaining a vitrified first additive powder by heat-treating a slurry containing MgO, SiO₂, and CaO; preparing a slurry by mixing an Al₂O₃ powder with the first additive powder, a second additive powder containing a MgO powder, and a third additive powder containing a Y₂O₃ powder; and forming the ceramic sheets by tape casting the slurry.

In the obtaining of the vitrified first additive powder, the weight ratio (wt%) of CaO, SiO₂, and MgO in the slurry may include 35-55:35-50:8-18.

In the forming of the ceramic sheets, the weight ratio (wt%) of the Al₂O₃ powder, the first additive powder, the second additive powder, and the third additive powder may be 94-98:1-3:0.5-1.5:0.5-1.5.

The grain size distribution of ceramic grains in the sintered body after the sintering may be 0.5 to 5 µm.

The thickness of the conductive metal material may be 10 to 30 µm.

The obtaining of the vitrified first additive powder may include sequentially performing mixing, melting, quenching, and grinding on the slurry containing MgO, SiO₂, and CaO.

The quenching may be water quenching.

According to the present disclosure, the method for manufacturing a ceramic susceptor can provide a ceramic susceptor having high volume resistivity without temperature dependence through a uniform composition thereof, whereby the ceramic susceptor, when applied to an electrostatic chuck, can perform stable chucking and de-chucking without electrostatic force changes and temperature dependency.

### BRIEF DESCRIPTION OF THE DRAWINGS

The accompanying drawings, which are included as a part of the description to help the understanding of the present disclosure, provide embodiments of the disclosure and, together with the description, explain the technical spirit of the present disclosure.

FIG. 1 is a diagram showing a structure of a ceramic susceptor, which is mainly used in a poly etch process, according to an embodiment of the present disclosure.

FIG. 2 is a flowchart showing a process of manufacturing a ceramic plate of a ceramic susceptor according to an embodiment of the present disclosure.

FIG. 3 is a flowchart specifically showing a manufacturing process for obtaining ceramic sheets of the present disclosure.

FIG. 4 shows an exemplary CaO—MgO—SiO₂ phase diagram in the reference paper.

FIG. 5A to FIG. 5C show SEM images of a ceramic sheet prepared according to the example on Table 2.

FIG. 6 shows component analysis results of conventional, inventive (novel), and comparative ceramic sheet sintered bodies.

FIG. 7A to FIG. 7C show comparison graphs of mechanical properties between an inventive (novel) example and a conventional art or a comparative example.

FIG. 8A shows the results of comparing etching depth in a silicon wafer, a comparative ceramic sheet, and an inventive (novel) ceramic sheet.

FIG. 8B shows SEM images of etched surfaces in a comparative ceramic sheet and an inventive (novel) ceramic sheet.

FIG. 9 is a table showing compositional ratios of inventive ceramic sheets manufactured with different compositional ratios (Case Nos. 0, 1, 2, and 3).

FIG. 10 shows the results of measuring volume resistivity and density of Case Nos. 0, 1, 2, and 3 in FIG. 9.

FIG. 11 is a graph showing volume resistivity with temperature in a conventional art not employing glassy powder addition.

FIG. 12 is a graph showing volume resistivity of Case Nos. 0, 1, 2, and 3 in FIG. 9.

FIG. 13 shows SEM images of surfaces of Case Nos. 0, 1, 2, and 3 in FIG. 9.

### DETAILED DESCRIPTION

Hereinafter, the present disclosure will be described in detail with reference to the accompanying drawings. In each drawing, like components are denoted by like reference numerals. Further, the detailed description of known functions and/or components will be omitted. The following disclosed contents mainly describe portions required to understand operations according to embodiments and the description of elements which make the gist of the description obscure will be omitted. Further, some of components of the drawings may be exaggerated, omitted, or schematically illustrated. A size of each component does not completely reflect a real size and therefore the contents disclosed herein are not limited by a relative size or interval of the components illustrated in the drawings.

When describing exemplary embodiments of the present disclosure, when it is determined that a detailed description with respect to known technology related to the present disclosure may unnecessarily obscure the gist of the present disclosure, a detailed description thereof will be omitted. The terminology used hereinafter is terms defined by considering a function in exemplary embodiments of the present disclosure, and their meaning may be changed according to intentions of a user and an operator, customs, or the like. Accordingly, the terminology will be defined based on the contents throughout this specification. The terminology used in the detailed description is used for describing exemplary embodiments of the present disclosure, and is not used for limiting the present disclosure. Elements of the present disclosure in the singular may number one or more, unless the context clearly indicates otherwise. It will be further understood that the terms “comprising”, “containing”, or “including” when used herein, specify the presence of certain features, figures, steps, operations, elements, components, or parts or combinations thereof, but do not preclude the presence or addition of one or more other features, figures, steps, operations, elements, or parts or combinations thereof.

The terms first, second, and the like may be used herein to describe various elements. These elements should not be limited by these terms, as these terms are only used to distinguish one element from another unless stated otherwise or the context clearly indicates otherwise.

First, a ceramic susceptor recited in the present disclosure is included in apparatuses for performing semiconductor processes, and may be used as an electrostatic chuck for holding various substrates, such as a glass substrate, a flexible substrate, and a semiconductor wafer substrate in a process, such as plasma enhanced chemical vapor deposition, or as a heater for accurate temperature control and heat treatment requirements in a plasma deposition process or the like to attain a precise process, such as providing finer wirings in semiconductor devices. The electrostatic chuck function is for holding a corresponding substrate by using electrostatic force, wherein chucking and de-chucking for securely holing the substrate by adsorption and releasing the substrate in apparatuses for ion injection or other semiconductor processes and, especially, sufficient clamping force is provided to enable chucking. In order to improve the chucking and de-chucking times of the substrate while maintaining the clamping pressure, chucking electrodes of the ceramic susceptor are driven by alternating current voltage. In addition to such substrate holding, the heater function may be performed by supplying electric power to radio frequency electrodes/heater electrodes of the ceramic susceptor for plasma formation and substrate heating in an etching process or a photoresist firing process on thin film layers formed on a semiconductor wafer substrate.

Hereinafter, the present disclosure will be described by an example wherein chucking electrodes of a ceramic susceptor are included in a ceramic plate and electric power is supplied to the chucking electrodes through electrode rods (electrostatic chuck function), but is not limited thereto. It is made clear in advance that the related description can be similarly applied to an embodiment of the present disclosure in which heater electrodes or radio frequency (RF) electrodes for plasma formation, instead of chucking electrodes of the ceramic susceptor, are included in the ceramic plate, and electric power is supplied to the heater/RF electrodes through electrode rods (heater/plasma function).

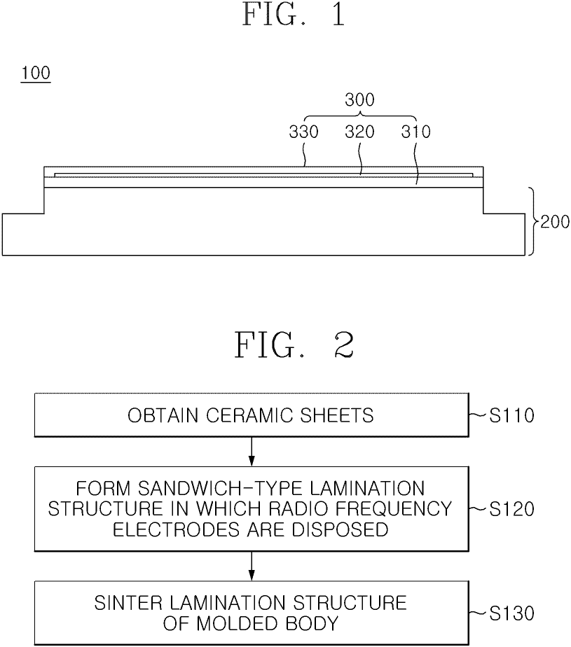

FIG. 1 is a diagram showing a structure of a ceramic susceptor 100, which is mainly used in a poly etch process according to an embodiment of the present disclosure.

Referring to FIG. 1, the ceramic susceptor 100 according to an embodiment of the present disclosure includes a base substrate 200 and a ceramic plate 300. The ceramic susceptor 100 is preferably in a circular type but, in some cases, may be designed in other shapes, such as an ellipse or a rectangle.

The base substrate 200 may be formed in a multi-layer structure composed of a plurality of metal layers. These metal layers may be bonded through a brazing process, a welding process, or a bonding process. The ceramic plate 300 is fixed on the base substrate 200, wherein the ceramic plate may be fixed on the base substrate 200 by using a predetermined fixing member or adhesive member. The base substrate 200 and the ceramic plate 300 may be manufactured separately and then bonded together and, in some cases, a structure of the ceramic plate 300 may be formed directly on an upper surface of the base substrate 200.

When the ceramic susceptor 100 is installed inside a chamber for a semiconductor process or the like, the base substrate 200 and the ceramic plate 300 may include a predetermined cooling structure (not shown) to uniformly cool a substrate (e.g., a glass substrate, a flexible substrate, a semiconductor wafer substrate, etc.) on the ceramic plate 300 by using a cooling gas from the outside. For example, the substrate on the ceramic plate 300 can be uniformly cooled by allowing a cooling gas to flow through cooling gas holes and cooling flow path patterns. In such a case, helium gas (He) may be mainly used as a cooling gas, but is not necessarily limited thereto.

In FIG. 1, the ceramic plate 300 includes a first ceramic sheet layer 310 as an insulating layer/dielectric layer, an electrode layer 320 including chucking electrodes on the first ceramic sheet layer 310, and a second ceramic sheet layer 330 as an insulating layer/dielectric layer on the electrode layer 320.

The chucking electrodes or the like of the electrode layer 320 may be formed of a conductive metal material. For example, the chucking electrodes or the like of the electrode layer 320 may be formed of at least one of silver (Ag), gold (Au), nickel (Ni), tungsten (W), molybdenum (Mo), and titanium (Ti), and more preferably tungsten (W). The electrode layer 320 may be formed using CVD, PVC, thermal spray coating, or screen printing. An electrode, for example, a DC electrode, of the electrode layer 320 may have a thickness of about 10 µm to 30 µm. For example, if the thickness of the electrodes of the electrode layer 320 is less than 10 µm, the resistivity value of the corresponding electrodes increases due to porosity and other defects in the corresponding electrode layer, and such an increased resistivity value causes a deterioration in electrostatic adsorption, and therefore such a thickness is not preferable. Alternatively, if the thickness of the electrodes of the electrode layer 320 is more than 30 µm, the stress in the interface between the ceramic and the electrode layer increases with the temperature change and, in some cases, arcing or the like may occur through partial separation, and thus such a thickness is not preferable. Therefore, the thickness of DC electrodes of the electrode layer 320 is preferably in a range of about 10 µm to 30 µm. The electrodes of the electrode layer 320 receive electric power through corresponding electrode rods (not shown), and receive a bias when a substrate (not shown) to be placed on the second ceramic sheet layer 330 is loaded, to generate electrostatic force, thereby chucking the substrate. When the substrate (not shown) is unloaded, the electrodes of the electrode layer 320 are discharged by applying an opposite bias thereto, and thus performs de-chucking.

The first ceramic sheet layer 310 and the second ceramic sheet layer 330 are formed of a ceramic material. According to the present disclosure, as described below, the first ceramic sheet layer 310 and the second ceramic sheet layer 330 may be formed by laminating a plurality of ceramic sheets to a required thickness while the electrode layer 320 is disposed between the ceramic sheet laminated products, and then sintering the ceramic sheets together with the electrode layer 320, wherein the ceramic sheets may be formed by: obtaining a vitrified first additive powder through mixing, melting, quenching, and grinding of a slurry containing MgO, SiO₂, and CaO; and mixing an Al₂O₃ powder with the first additive powder, a second additive powder containing a MgO powder, and a third additive powder containing a Y₂O₃ powder.

As described above, although not shown in the drawings, the ceramic plate 300 in the present disclosure may further include, in addition to the electrodes 320, heater electrodes and corresponding electrode rods for the heater function, between ceramic materials, or the ceramic sheet layers as above. Therefore, the ceramic plate 300 may be configured such that the chucking electrodes 320 and (or) heater/RF electrodes are disposed (embedded) to be above and below separated from each other with a ceramic material interposed therebetween at a predetermined interval. Therefore, the ceramic plate 300 may be configured so as to enable a substrate to be processed to undergo heating and (or) plasma enhanced chemical vapor deposition while stably holding the substrate. The ceramic plate 300 may be formed in a plate-like structure having a predetermined shape. For example, the ceramic plate 300 may be formed in a plate-like structure and, preferably, has a circular shape shown in the plan view above, but is not necessarily limited thereto.

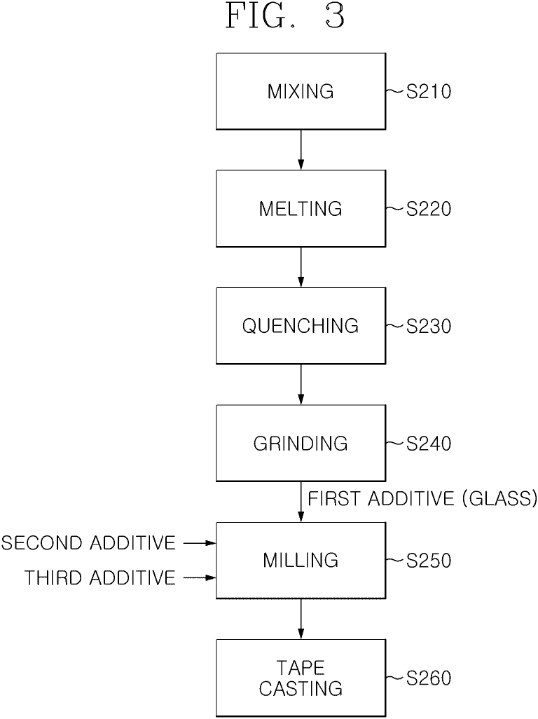

FIG. 2 is a flowchart showing a process of manufacturing a ceramic plate 300 of a ceramic susceptor 100 according to an embodiment of the present disclosure.

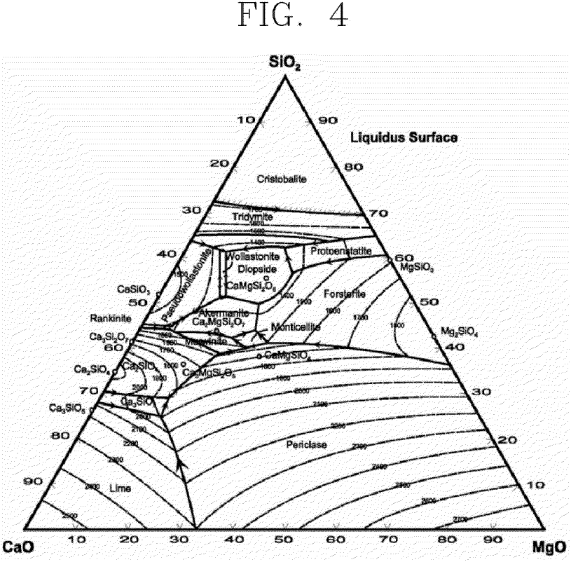

Referring to FIG. 2, in order to manufacture the ceramic plate 300 for the ceramic susceptor 100 according to an embodiment of the present disclosure, ceramic sheets for forming the first ceramic sheet layer 310 and the second ceramic sheet layer 330 are prepared (S110). The manufacturing process of the ceramic sheets will be described in detail with reference to FIG. 3.

Then, a laminated structure with a sandwich structure in which electrodes of an electrode layer 320 are disposed is molded (S120). That is, a molded body is manufactured in which a conductive metal material for the electrodes of the electrode layer 320 are disposed between the first ceramic sheet layer 310 and the second ceramic sheet layer 330 each including a plurality of ceramic sheet layers. For example, a plurality of ceramic sheets for the first ceramic sheet layer 310 are laminated to a required thickness on a predetermined stage or carrier film. The first ceramic sheet layer 310 can be easily fixed and supported by disposing an adhesive or the like on the stage or the carrier film. The conductive metal material for the electrodes of the electrode layer 320 is disposed thereon. The disposition of the conductive metal material may be performed by a printing method, such as screen printing. The thickness of the conductive metal material may be 10 µm to 30 µm. In addition, a plurality of ceramic sheets for the second ceramic sheet layer 330 are laminated to a required thickness on the conductive metal material. A conductive metal material for heat electrodes/RF electrodes for a heater/plasma function may be further disposed in addition to chucking electrodes of the electrode layer 320. As described above, for the manufacture of the ceramic susceptor 100 further including heater electrodes/RF electrodes for a heater function in addition to the chucking electrodes of the electrode layer 320, a conductive metal material for heater electrodes/RF electrodes may be further disposed on the second ceramic sheet layer 330. In such a case, a plurality of ceramic sheets for a third ceramic sheet layer may be laminated to a required thickness on the conductive metal material for the heater electrodes/RF electrodes.

Then, a degreasing process in a reducing atmosphere for removing carbon contained in a corresponding lamination structure of a molded body corresponding to the entire shape of a body part of the susceptor 100 constituting the ceramic susceptor 100 and a pressureless sintering process in a reducing atmosphere for preventing electrode oxidation may be performed (S130).

For example, the degreasing process and the pressureless sintering process may be performed on the molded body by using predetermined molding mold and pressing mold as follows. That is, a degreasing process may be first performed on a corresponding lamination structure of a molded body subjected to the lamination of a plurality of ceramic sheets for the first ceramic sheet layer 310, the disposition of a metal material for the electrode layer 320, and the lamination of a plurality of ceramic sheets for the second ceramic sheet 330 (additionally, if necessary, the lamination of a plurality of ceramic sheets and the disposition of a metal material for heater electrodes/RF electrodes). In the degreasing process, high-temperature heat is provided in a reducing atmosphere to remove polymer compounds remaining inside the corresponding lamination structure of the molded body, thereby removing carbon compounds in the lamination structure. The temperature of the degreasing process is preferably 500 to 700° C. The molded body undergoing the degreasing process may be subjected to pressureless sintering in a reducing atmosphere to prevent oxidation of the electrodes. The pressureless sintering is performed at a high temperature so as to induce the densification of alumina particles in the lamination structure of the molded body. The temperature of the pressureless sintering process is preferably 1500 to 1700° C.

FIG. 3 is a flowchart specifically showing a manufacturing process for obtaining ceramic sheets of the present disclosure.

Referring to FIG. 3, the preparation process for obtaining ceramic sheets for the ceramic sheet layers 310 and 330 may include processes, such as mixing (S210), melting (S220), water quenching (S230), grinding (S240), milling (S250), and tape casting (S260).

That is, a slurry containing MgO, SiO₂, and CaO is treated through mixing (S210), melting (S220), quenching (S230), and grinding (S240) to obtain a vitrified first additive powder, and then an Al₂O₃ powder is mixed and processed with the first additive powder, a second additive powder containing a MgO powder, and a third additive powder containing a Y₂O₃ powder through milling (S250) and tape casting (S260) to form a ceramic sheet.

First, to obtain the vitrified first additive powder, in the mixing (S210) process, a slurry containing MgO, SiO₂, and CaO, that is, a slurry containing CaO, SiO₂, and MgO at a weight ratio of 35-55 wt%:35-50 wt%:8-18 wt%, or approximately a weight ratio (wt%) of CaO, SiO₂, and MgO of 1 :0.7:0.3 is mixed through a predetermined mixer. The slurry may partially contain a solvent (e.g., water or alcohol) and a dispersant.

In the melting (S220) process, the slurry is placed in a crucible (e.g., a Pt crucible) and heated to melt. In addition, the melting (S220) process may be performed at 1100 to 1600° C. for 1 to 3 hours, preferably at 1400 to 1500° C. for 2 hours.

In the water quenching (S230) process, in order to vitrify the slurry that has been transformed into a liquid phase by treatment in the melting (S220) process, the slurry is cooled with water, wherein a container receiving the slurry transformed into a liquid phase is quenched with water in a predetermined water quencher to thereby rapidly cool the slurry, so that the slurry transformed into a liquid phase is vitrified to generate a glassy solid.

In the grinding (S240) process, the glassy solid generated in the water quenching (S230) process is made into a powder (glassy first additive powder) with a diameter of about 0.3 to 1.0 µm through grinding using a bead mill or the like. By the mixing of CaO, SiO₂, and MgO, the glassy first additive powder may be obtained in a glassy solid state, such as CaMgSiO₄, CaMgSi₂O₆, or CaMg(Si₂O₇).

In the milling (S250) process, an Al₂O₃ powder is uniformly mixed with the first additive powder, a second additive powder containing a MgO powder, and a third additive powder containing a Y₂O₃ powder by using a ball mill. For example, the weight ratio of the Al₂O₃ powder, the first additive powder (glassy powder containing MgO, SiO₂, and CaO), the second additive powder (MgO powder), and the third additive powder (Y₂O₃ powder) may be contained at 94 to 98 wt%:1 to 3 wt%:0.5 to 1.5 wt%:0.5 to 1.5 wt%. Approximately, the weight ratio of the Al₂O₃ powder, the first additive powder (glassy powder containing MgO, SiO₂, and CaO), the second additive powder (MgO powder), and the third additive powder (Y₂O₃ powder) may be about 96:2:1:1.

In the tape casting (S260) process, the mixture powder treated in the milling (S250) process is mixed with a solvent, a binder, a dispersant, a plasticizer, and the like at an appropriate ratio to prepare a slurry, and then molded into a plate of uniform thickness on a carrier film and dried to thereby prepare a tape-shaped ceramic sheet.

As described above, according to the method for manufacturing the ceramic susceptor 100 of the present disclosure, in the preparation of ceramic sheets to be applied to the ceramic susceptor 100, such as a high-temperature ceramic electrostatic chuck or heater, Al₂O₃ is used as a main ceramic, and MgO, SiO₂, CaO, and Y₂O₃ are added as additives for attaining a high volume resistivity value. In particular, the slurry of MgO, SiO₂, and CaO to be added is first vitrified (made glassy) by high-temperature melting and then rapid cooling, and made into glassy powder, and thereafter, the glassy powder, a MgO powder, Y₂O₃ powder, and the like are again added to an Al₂O₃ powder to prepare ceramic sheets.

As set forth in the present disclosure, a vitrified composition is required for high-volume resistivity ceramics, and for the improvement in high-temperature stability of a material, a sintering additive was synthesized as a glass with a high melting point and added. The glass enables a ceramic base material to have a relative density of 98% or more by promoting the sinterability of the ceramic base material. In addition, MgO and Y₂O₃ were further added for controlling grain growth and improving high-temperature characteristics, wherein the further added MgO suppresses the non-uniform grain growth of Al₂O₃ ceramics, so that a sintered body after sintering (S130), that is, the ceramic plate 300, includes ceramic particles with a grain size distribution of 0.5 to 5 µm, an average of about 3 µm, and thus maintains high strength and retains increased plasma resistance.

### Example 1

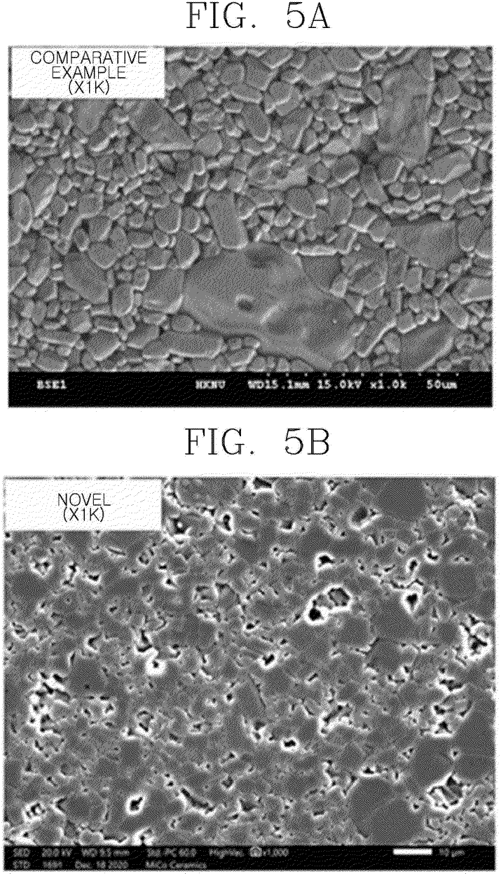

According to an example of the present disclosure, a sintering additive of CaMgSi₂O₆ having a glassy composition and a high melting point as shown in FIG. 4 was synthesized through a slurry containing MgO, SiO₂, and CaO (Table 1). FIG. 4 shows an exemplary CaO—MgO—SiO₂ phase diagram in the reference paper. The paper “Fundamentals of Eaf and Ladle Slags and Ladle Refining Principles, Semantic Scholar, 2021” was referenced.

TABLE 1

| Product | Chemical Formula | Melting point (°C) | Crystal System |
|---|---|---|---|
| Diopside | CaMgSi₂O₆ | 1391 | Monoclinic |

A ceramic sheet was prepared by further adding a glassy powder (glass), a MgO powder, a Y₂O₃ powder, and the like to an AI₂O₃ powder as shown in Table 2.

TABLE 2

| Raw materials | Al₂O₃ | MgO | Y₂O₃ | Glass |
|---|---|---|---|---|
| Addition amount (wt%) | 96 | 1 | 1 | 2 |

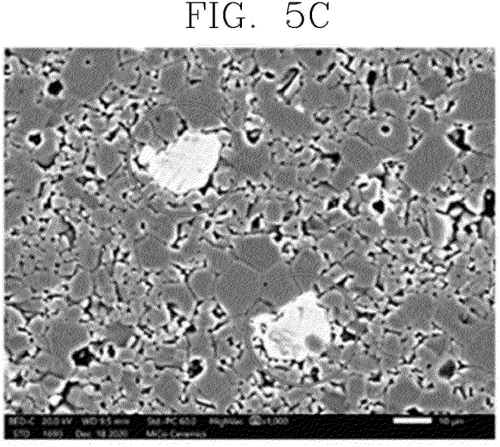

FIG. 5A to FIG. 5C show scanning electron microscope (SEM) images of a surface of a ceramic sheet prepared according to the example on Table 2. FIG. 5A shows a comparative example (e.g., a commercial product) of a ceramic sheet; FIG. 5B shows an inventive example as shown in Table 2; and FIG. 5C shows a locally crystallized glass region of the inventive example as shown in Table 2.

As shown in FIG. 5B, it was confirmed that non-uniform grain growth can be suppressed by adjusting the addition amount of the sintering additive as shown in Table 2. As shown in FIG. 5C, it was confirmed that a rare earth material such as Y₂O₃ was added to locally form crystallized glass centering on the rare earth material.

### Example 2

According to another example of the present disclosure, a glassy powder having a high melting point was prepared through a slurry containing MgO, SiO₂, and CaO, followed by addition, thereby preparing a ceramic sheet, of which the content of each component is included within a compositional range of a comparative example.

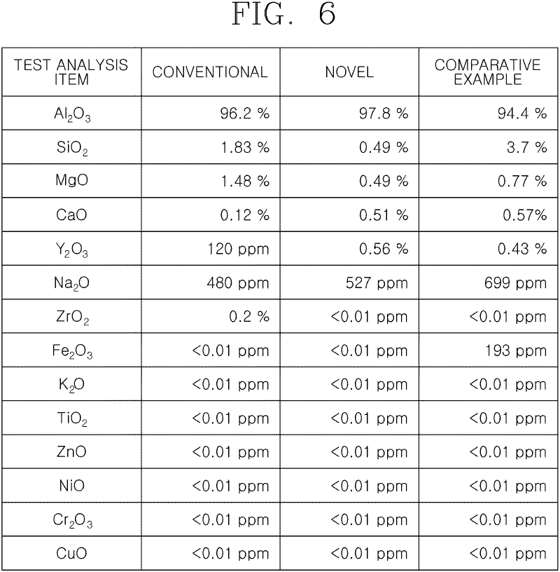

FIG. 6 shows component analysis results of conventional (no glassy powder being added), inventive (novel), and comparative ceramic sheet sintered bodies.

The inventive ceramic sheet having a composition shown in the example of FIG. 6 showed a density of 3.94 g/cm³ (measured) higher than a density of 3.84 g/cm³ of the comparative example.

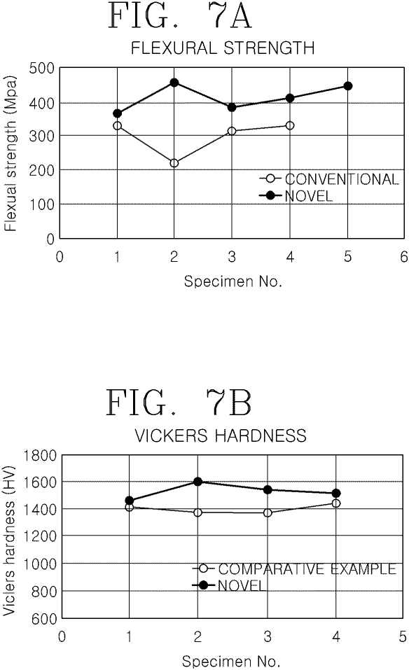

FIG. 7A to FIG. 7C shows comparison graphs of mechanical properties between an inventive (novel) example and a conventional art (no glassy powder being added) or a comparative example.

FIG. 7A to FIG. 7C confirmed that the inventive ceramic sheet showed improved flexural strength (FIG. 7A), Vickers hardness (FIG. 7B), and volume resistivity (FIG. 7C) compared with the conventional art and the comparative example. Especially, as shown in FIG. 7C, it was confirmed that the inventive ceramic sheet showed improved high-temperature volume resistivity characteristics due to a high-temperature molten liquid phase and a rare earth material.

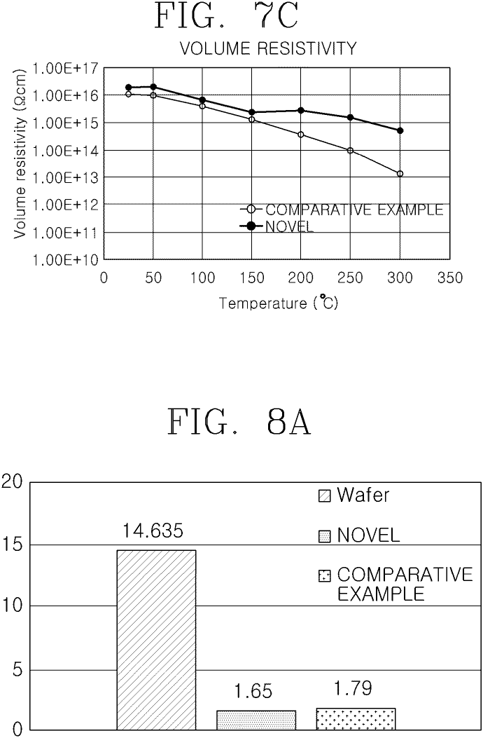

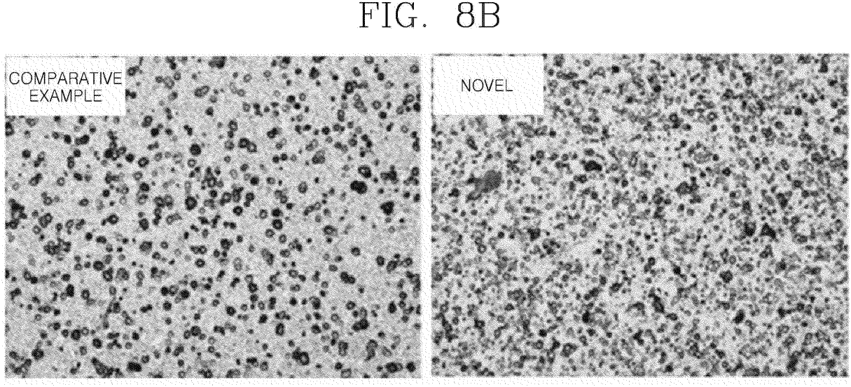

FIG. 8A shows the results of comparing etching depth in a silicon wafer, a comparative ceramic sheet, and an inventive (novel) ceramic sheet.

FIG. 8B shows SEM images of etched surfaces in a comparative ceramic sheet and an inventive (novel) ceramic sheet.

As shown in FIG. 8A, under the same etching conditions using a predetermined etching solution, the inventive (novel) ceramic sheet showed an etching depth (1.65), which was relatively lower than the etching depth (1.79) in the comparative ceramic sheet as well as in the silicon wafer. FIG. 8B confirmed that the groove size on the surface of the inventive (novel) ceramic sheet was smaller than that of the comparative ceramic sheet, indicating that the inventive (novel) ceramic sheet was densified and composed of fine grains.

### Example 3

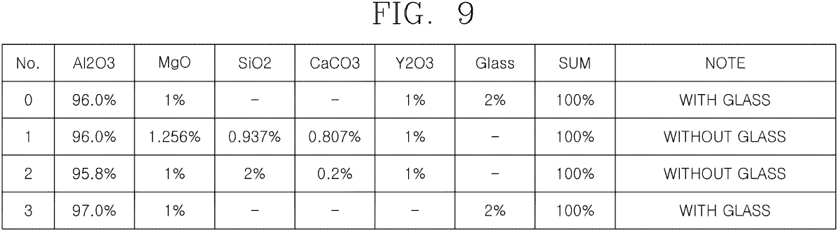

FIG. 9 is a table showing compositional ratios of inventive ceramic sheets manufactured with different compositional ratios (Case No. 0, 1, 2, and 3).

As shown in FIG. 9, no glassy powder was added in Case No. 2; a glassy powder, a MgO powder, and a Y₂O₃ powder were added as additives in Case No. 0; the mixing ratio of raw materials for the glassy powder of Case No. 0 was calculated and such raw materials were added, in Case No. 1; an arbitrarily selected mixing ratio of raw materials was used in Case No. 2; and the addition of a Y₂O₃ powder was excluded compared with Case No. 0, in Case No. 3.

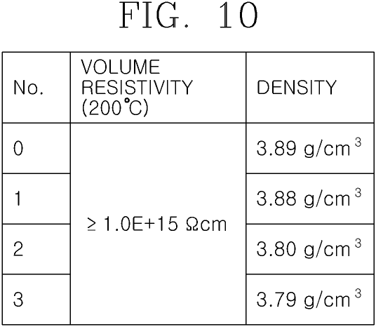

FIG. 10 shows the results of measuring volume resistivity and density of Case Nos. 0, 1, 2, and 3 in FIG. 9.

As shown in FIG. 10, all the cases showed a density of 3.79 g/cm3 or more and a volume resistivity of 1015 Ωcm or more at 200° C.

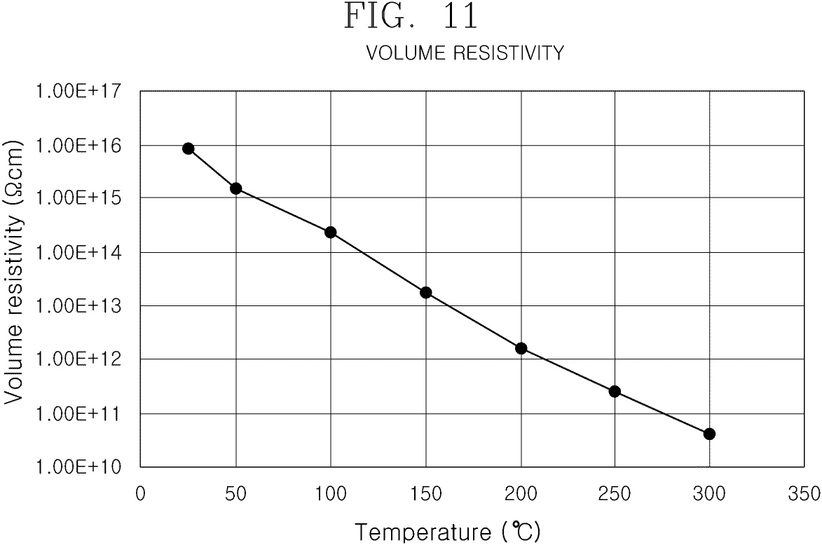

FIG. 11 is a graph showing volume resistivity with temperature in a conventional art not employing glassy powder addition.

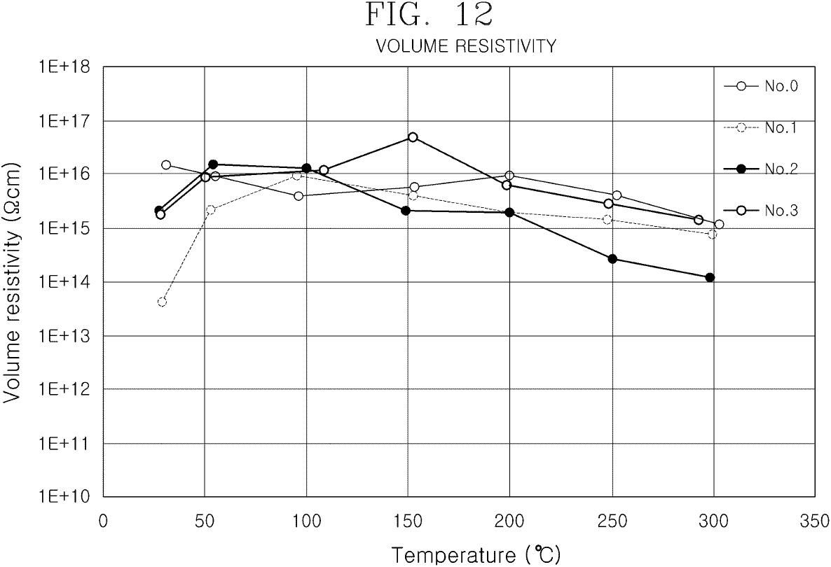

FIG. 12 is a graph showing volume resistivity of Case Nos. 0, 1, 2, and 3 in FIG. 9.

As shown in FIG. 11, the volume resistivity of the conventional art was smaller than 1012 Ωcm at 200° C. or higher. However, Case Nos. 0, 1, 2, and 3, which were all the cases in FIG. 9, maintained a volume resistivity of approximately 10¹⁵ Ωcm or higher at 200° C. or higher.

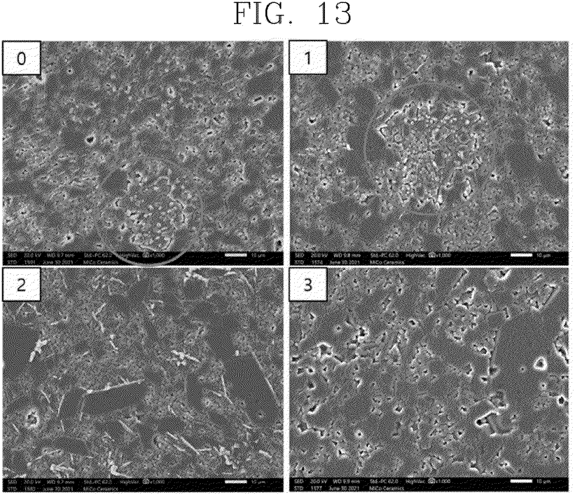

FIG. 13 shows SEM images of surfaces of Case Nos. 0, 1, 2, and 3 in FIG. 9.

FIG. 13 confirmed that in Case No. 0 (a glassy powder and MgO and Y₂O₃ powders as additives being used), yttria (Y₂O₃) was melted in the glass and present in the interface as shown in the circle mark region. In Case No. 0 and Case No. 1 where a glassy powder was excluded compared with Case No. 0, grains expected to be crystallized glass were found as shown in the circle mark region.

In Case No. 1, most yttria was present as grains, and in Case Nos. 1 and 2, there was a change in shrinkage depending on directivity. In Case No. 2 (no glassy powder being added), a plurality of abnormal grains were grown. In Case No. 3 (the addition of a Y₂O₃ powder being excluded compared with Case No. 0), crystallized glass was not found due to the non-addition of yttria.

In addition, as a result of energy dispersive X-ray spectroscopy (EDS) measurement, it was confirmed that relatively large amounts of glass and yttria were contained in Case No. 0 (a glassy powder and MgO and Y₂O₃ powders being used as additives). This indicates that grains grew while absorbing neighboring grains at positions thereof but not the interface.

As set forth above, the method for manufacturing a ceramic susceptor 100 according to the present disclosure can provide a ceramic susceptor 100 having high volume resistivity without temperature dependency through a uniform composition thereof, whereby the ceramic susceptor, when applied to an electrostatic chuck, can perform stable chucking and de-chucking without electrostatic force changes and temperature dependency.

The specified matters and limited exemplary embodiments and drawings such as specific elements in the present disclosure have been disclosed for broader understanding of the present disclosure, but the present disclosure is not limited to the exemplary embodiments, and various modifications and changes are possible by those skilled in the art without departing from an essential characteristic of the present disclosure. Therefore, the spirit of the present disclosure is defined by the appended claims rather than by the description preceding them, and all changes and modifications that fall within metes and bounds of the claims, or equivalents of such metes and bounds are therefore intended to be embraced by the range of the spirit of the present disclosure.

What is claimed is:

1. A method for manufacturing a ceramic susceptor, the method comprising:
preparing ceramic sheets;
preparing a lamination structure of a molded body, in which the ceramic sheets are laminated and a conductive metal layer for electrodes is disposed between the ceramic sheet laminated products; and
sintering the lamination structure of the molded body,
wherein the preparing of the ceramic sheets includes:
obtaining a vitrified first additive powder by heat-treating a slurry containing MgO, SiO₂, and CaO;
preparing a slurry by mixing an Al₂O₃ powder with the first additive powder, a second additive powder containing a MgO powder, and a third additive powder containing a Y₂O₃ powder; and
forming the ceramic sheets by tape casting the slurry.

2. The method of claim 1, wherein in the obtaining of the vitrified first additive powder, the weight ratio (wt%) of CaO, SiO₂, and MgO in the slurry includes 35-55:35-50:8-18.

3. The method of claim 1, wherein in the forming of the ceramic sheets, the weight ratio (wt%) of the Al₂O₃ powder, the first additive powder, the second additive powder, and the third additive powder is 94-98:1-3:0.5-1.5:0.5-1.5.

4. The method of claim 1, wherein the grain size distribution of ceramic grains in the sintered body after the sintering is 0.5 to 5 µm.

5. The method of claim 1, wherein the thickness of the conductive metal material is 10 to 30 µm.

6. The method of claim 1, wherein the obtaining of the vitrified first additive powder comprises sequentially performing mixing, melting, quenching, and grinding on the slurry containing MgO, SiO₂, and CaO.

7. The method of claim 1, wherein the quenching is water quenching.
